(19) United States
(12) Patent Application Publication
(10) Pub. No.: US 2002/0199141 A1
(43) Pub. Date: Dec. 26, 2002

(54) Calibration apparatus and method for automatic test equipment

(76) Inventors: Carol Lemlein, Santa Monica, CA (US); Timothy Derksen, Thousand Oaks, CA (US)

Correspondence Address: Legal Department, Teradyne, Inc., 321 Harrison Avenue, Boston, MA, 02118, US

(21) Appl. No.: 09/885,583

(22) Filed: Jun. 20, 2001

(51) Int. Cl. H01L 21/66; G01R 31/26; G01R 31/28

(52) U.S. Cl. 714/724; 438/14

(57) ABSTRACT

Automatic test equipment for testing a plurality of devices-under-test is disclosed. The equipment includes a plurality of channel modules, each of the channel modules having a plurality of channels with each channel corresponding to a pin of one of the devices-under-test. Programmable delay circuitry is coupled to each channel module. The programmable delay circuitry includes a deskew circuit adapted to be shared by more than one of the channels of the coupled channel module.

### FIELD OF THE INVENTION

The invention relates generally to automatic test equipment and more particularly a calibration circuit arrangement and method to minimize hardware costs while maximizing accuracy.

### BACKGROUND OF THE INVENTION

Semiconductor device manufacturing typically includes test processes at both the wafer and packaged-device levels. The testing is normally carried out by automatic test equipment ATE that simulates a variety of operating conditions to verify the functionality of each device. Depending upon a device's complexity and function, it may be tested in parallel with other devices to increase throughput for the semiconductor manufacturer and lower test costs. Memory devices, in general, are a good example of devices that are typically tested in parallel.

Referring to FIG. 1, a typical semiconductor tester 10 generally includes a computer workstation 12 coupled to a databus 14 that routes signals to and from pattern generation circuitry 16, timing circuitry 18 and failure processing circuitry 20. The timing circuitry responds to programmed patterns from the pattern generator to provide precisely timed tester events. The events, in turn, activate driver/comparator circuitry 22 that interfaces to a plurality of devices-under-test (DUTs) 24.

As the speeds of modern semiconductors increase, the edge-placement accuracy requirements for testing the devices become more stringent. Edge-placement accuracy generally refers to the acceptable offset of a rising or falling signal “edge” with respect to another edge or reference point. Consequently, ATE manufacturers must balance cost, parallelism and accuracy, among other things, when designing ATE for widespread acceptance by semiconductor manufacturers.

Like any sophisticated measuring instrument, a semiconductor tester often requires calibration of its channels in order to maintain expected edge-placement accuracy levels. With further reference to FIG. 1, calibration circuitry 26 modifies the timing circuitry output signals as needed to compensate for signal degradation and skews on the individual channels 28. Calibration often involves detecting channel-to-channel timing skews, and providing compensating delays to the tester signals during the test to account for the skew. This is important in order to ensure that all the signal edges applied to or captured from the DUTs on a given cycle are done so at the DUT pins synchronously.

Conventionally, and with reference to FIG. 2, each tester channel 28 has a corresponding deskew circuit 30 for adding a programmable (adjustable) delay to the signal path. Prior to testing a plurality of semiconductor devices 24, the deskew circuits are programmed for testing all the channels in parallel.

While this one-to-one calibration circuit per channel hardware architecture and associated calibration method works well for its intended applications, the amount of hardware involved contributes to the overall cost of test. Thus, to desirably reduce test costs, it would be beneficial to reduce calibration hardware costs while still retaining the required level of accuracy. The apparatus and method of the present invention addresses these needs.

### SUMMARY OF THE INVENTION

The calibration apparatus and method of the present invention provides multiple accuracy modes for a parallel tester while reducing calibration hardware costs. As a result, semiconductor device manufacturers can maximize device throughput, yields and correspondingly reduce test costs.

To realize the foregoing advantages, the invention in one form comprises automatic test equipment for testing a plurality of devices-under-test. The equipment includes a plurality of channel modules, each of the channel modules having a plurality of channels with each channel corresponding to a pin of one of the devices-under-test. Programmable delay circuitry is coupled to each channel module. The programmable delay circuitry includes a deskew circuit shared by more than one of the channels of the coupled channel module.

In another form, the invention comprises a method of calibrating channels of a parallel tester having calibration circuitry shared with tester channels. The method includes the steps of determining the level of accuracy required from the calibration circuitry to calibrate the channels; collecting deskew data for the identified channels; optimizing the collected deskew data; and storing the deskew data associated with the selectively identified channels.

In yet another form, the invention comprises a method of testing a plurality of DUTs with a semiconductor tester. The tester includes a plurality of channels formed into modules, with the channels of each module coupled to pins of different DUTs. Each module of channels have inputs coupled to a shared programmable delay circuit. The method includes the steps of selecting a group of DUTs to test; identifying the channels from each module coupled to each pin of the selected DUTs; loading optimized calibration data for the identified channels into the programmable delay circuit; testing the selected DUTs; and continuing the selecting, identifying, loading and testing steps until all of the DUTs are tested.

Other features and advantages of the present invention will be apparent from the following detailed description when read in conjunction with the accompanying drawings.

### BRIEF DESCRIPTION OF THE DRAWINGS

The invention will be better understood by reference to the following more detailed description and accompanying drawings in which

FIG. 1 is a block diagram of a conventional semiconductor tester;

FIG. 2 is a block diagram of the conventional calibration and channel circuitry;

FIG. 3 is a block diagram of the calibration and channel circuitry according to one form of the present invention;

FIG. 4 is a flowchart illustrating steps according to another form of the present invention; and

FIG. 5 is a flowchart illustrating steps according to a further form of the invention.

### DETAILED DESCRIPTION OF THE INVENTION

The calibration apparatus and method of the present invention minimizes calibration hardware costs attributable to the cost of ATE by selectively sharing individual calibration circuits with multiple channels. Accuracy levels for the calibration are user-changeable based on a plurality of selectable calibration and testing modes.

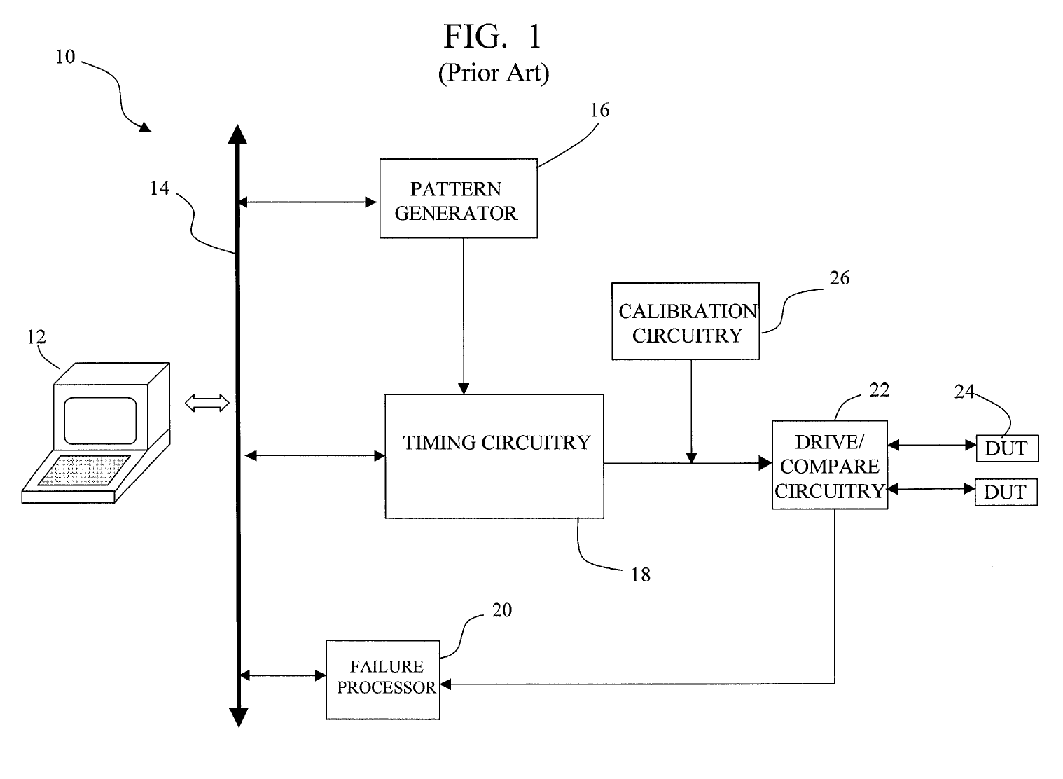

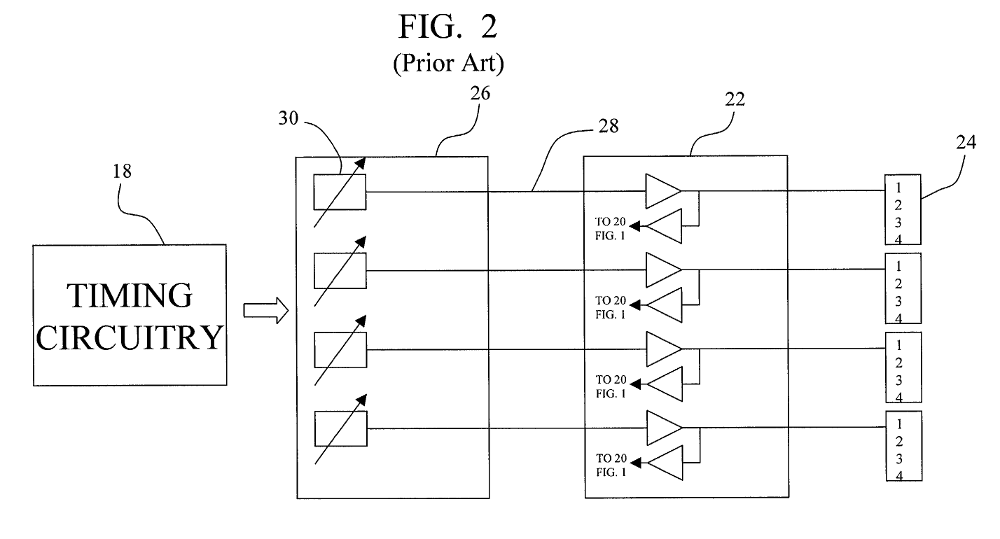

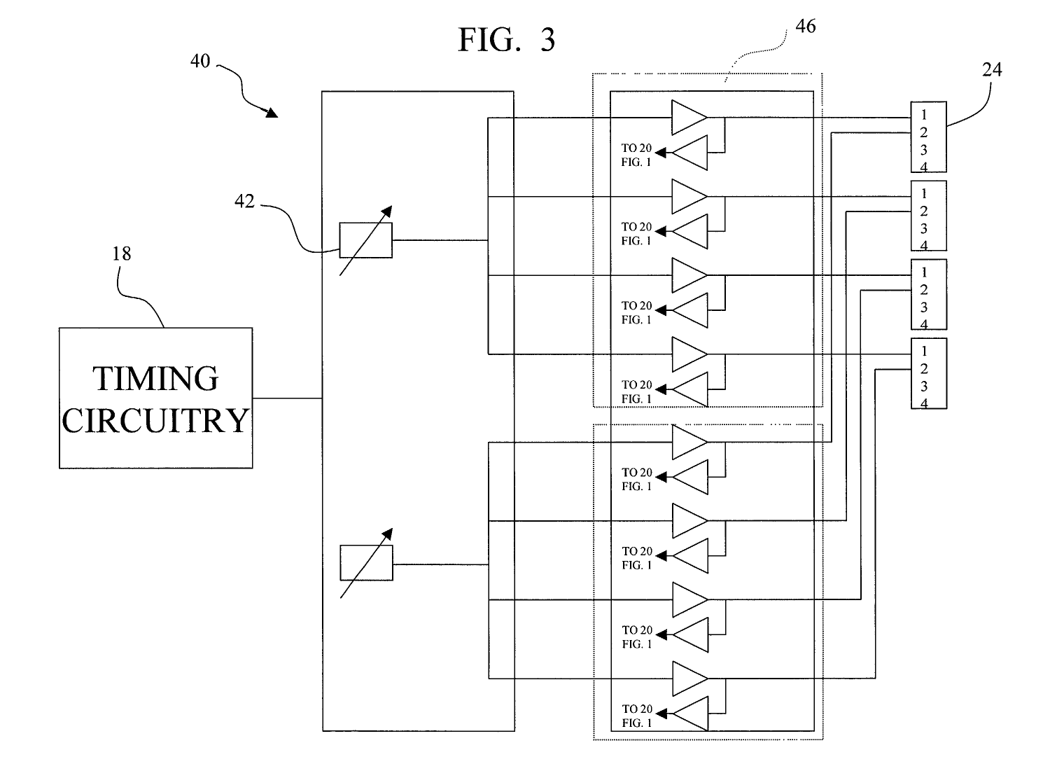

Referring to FIGS. 1 through 3, wherein like numerals refer to like features, automatic test equipment (ATE) 10 employing the calibration apparatus of the present invention includes many of the general features found in conventional ATE. Similar features include the computer workstation 12, databus 14, pattern generation circuitry 16, timing circuitry 18, failure processing circuitry 20, and driver/comparator circuitry 22. The calibration circuitry of the present invention, generally designated 40 (FIG. 3), however, differs uniquely from the conventional calibration circuitry 26 of FIG. 2.

With particular reference to FIG. 3, the calibration circuitry 40, according to one form of the invention, includes a plurality of deskew circuits 42 connected to respective channel modules 46 (in phantom). Each channel module preferably comprises a plurality of driver/comparator channels 48 for straightforward implementation on an application-specific-integrated-circuit (ASIC). The net effect of this architecture results in the deskew circuits being shared by the channels of each module. Moreover, the channels of each module are preferably routed to different pin locations (1, 2, 3, and 4 of each DUT 24) to enable high accuracy calibration and testing as more fully described below.

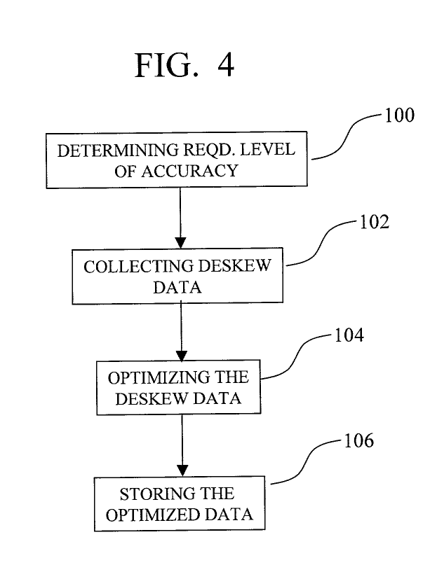

Referring now to FIG. 4, the calibration method according to another form of the invention takes advantage of the shared deskew architecture described above by first determining the required level of accuracy, at step 100. If the accuracy requirements are moderate, then all of the channels of each channel module 46 are identified and activated, at step 102, to collect deskew data, at step 104, by skew detectors (not shown). Data collection may be effected by, for example, time-domain-reflectometry (TDR) procedures or any acceptable timing measurement method.

Once the data is collected, at step 104, the calibration software then optimizes the data for each module, at step 106, by determining the maximum range of skews between the channels, and finding an average compensating delay that provides the required test accuracy. The optimized data is then stored in a memory, at step 108, to be reloaded prior to device testing.

With continuing reference to FIG. 4, high accuracy applications employ a similar calibration scheme to the moderate accuracy approach. The required level of accuracy is first determined (here, high) at step 100, followed by collecting deskew data for each individual channel by the skew detectors (not shown), at step 102. Since the deskew data for each channel is essentially a customized characterization of the channel (no averaging involved), optimizing the data, at step 104, involves merely preserving the data. The deskew data is then stored, at step 106, into a calibration table (memory) that cross-references the data to that particular channel.

Once the channels are calibrated, the tester is ready to test semiconductor devices, whether still formed on the semiconductor wafer (probe test) or packaged (handler test). Testing steps that take advantage of the calibration method described above are more fully detailed below.

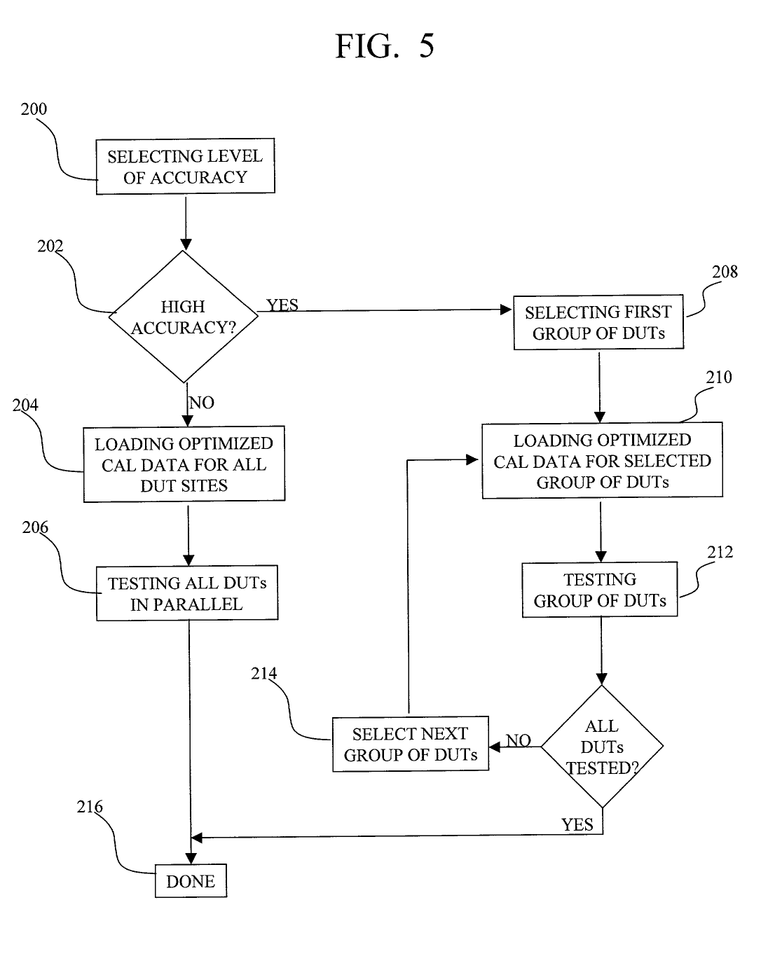

Referring now to FIG. 5, the level of accuracy for testing is first selected by the user, at step 200. The tester then determines the appropriate accuracy mode, at step 202. For the moderate accuracy mode, the optimized calibration data is loaded, at step 204, into the deskew circuits to provide an averaged delay to compensate for skew detected during the calibration routine. The devices-under-test (DUTs) are then all tested in parallel, at step 206, subject to the available number of tester channels. In this manner, high throughput is achieved while benefiting from reduced hardware costs.

With continuing reference to FIG. 5, in high accuracy mode, the testing is carried out a bit differently than the moderate accuracy mode. After the high accuracy mode is determined, at step 202, a first group of DUTs are selected, at step 208, with a ratio corresponding to the number of channels per deskew circuit. In other words, if there are four channels per deskew circuit, then one-quarter of the DUTs are selected for the first test pass. The calibration data for the selected channels is then loaded, at step 210, into the deskew circuits in order to test the DUTs at high accuracy, at step 212. The next group of DUTs is then selected, at step 214, followed by the data loading and testing steps described above. This sequence of steps repeats until all of the DUTs are tested, at step 216.

Those skilled in the art will appreciate the many benefits and advantages afforded by the present invention. In particular, calibration hardware costs are reduced by sharing deskew circuits among multiple channels without affecting moderate accuracy requirements. Moreover, multiple testing modes for varying accuracy requirements are achievable with no hardware modifications, but rather by merely employing unique calibration and testing steps with the calibration hardware noted above.

While the invention has been particularly shown and described with reference to the preferred embodiments thereof, it will be understood by those skilled in the art that various changes in form and detail may be made therein without departing from the spirit and scope of the invention.

What is claimed is:

1. Automatic test equipment for testing a plurality of devices-under-test, each of the devices-under-test having a predetermined number of input/output contact points for receiving and outputting signals, said automatic test equipment including:
a plurality of channel modules, each of the channel modules having a plurality of channels, each channel corresponding to one of the contact points; and
programmable delay circuitry coupled to each channel module, the programmable delay circuitry including a deskew circuit shared by more than one of the channels of the coupled channel module.

2. Automatic test equipment according to claim 1 wherein:
each channel module comprises an integrated circuit formed with more than one channel.

3. A method of calibrating channels of a parallel tester having calibration circuitry shared with tester channels, the method including the steps of:
determining the level of accuracy required from the calibration circuitry to calibrate the channels;
collecting deskew data for the channels;
optimizing the collected deskew data; and
storing the deskew data.

4. A method of calibrating channels of a parallel tester according to claim 3 wherein said optimizing step includes:
averaging the deskew data from more than one channel.

5. A method of calibrating channels of a parallel tester according to claim 3 wherein said optimizing step includes:
averaging the deskew data from all of the channels in parallel.

6. A method of calibrating channels of a parallel tester according to claim 3 wherein said optimizing step includes:
utilizing the individual deskew data for each channel.

7. A method of calibrating semiconductor tester channels for subsequently testing a plurality of DUTs, the tester channels being formed into modules, the channels of each module coupled to pin locations for different DUT locations, each module of channels having inputs coupled to shared calibration circuitry, the method including the steps of:
selecting a set of DUT locations;
identifying each tester channel from each module coupled to the selected DUT locations;
collecting deskew data for each of the identified channels with the shared deskew circuitry;
optimizing the collected deskew data;
storing the optimized deskew data for use during device testing; and
continuing the selecting, identifying, collecting, optimizing and storing steps until all of the tester channels are calibrated.

8. A method of calibrating semiconductor tester channels according to claim 7 wherein:
the optimizing step includes averaging the collected deskew data for groups of channels.

9. A method of calibrating semiconductor tester channels according to claim 7 wherein:
the optimizing step includes using the collected deskew data as the calibration data for each channel.

10. A method of testing a plurality of DUTs with a semiconductor tester, the tester including a plurality of channels formed into modules, the channels of each module coupled to pins of different DUTs, each module of channels having inputs coupled to a shared programmable delay circuit, the method including the steps of:
selecting a group of DUTs to test;
identifying the channels from each module coupled to each pin of the selected DUTs;
loading optimized calibration data for the identified channels into the programmable delay circuit;
testing the selected DUTs; and
continuing the selecting, identifying, loading and testing steps until all of the DUTs are tested.
